(19) United States
(12) Patent Application Publication
(10) Pub. No.: US 2026/0305124 A1
(43) Pub. Date: Oct. 1, 2026

(54) ORGANIC LIGHT EMITTING DISPLAY DEVICE

(71) Applicant: LG DISPLAY CO., LTD., Seoul (KR)

(72) Inventors: Min Ki KIM, Paju-si (KR); Sung Goo JUNG, Paju-si (KR); Hak Min LEE, Paju-si (KR)

(21) Appl. No.: 19/437,333

(22) Filed: Dec. 31, 2025

(30) Foreign Application Priority Data
Mar. 28, 2025 (KR) 10-2025-0040275

(51) Int. Cl. H10K 59/80; H10K 59/121; H10K 59/38; H10K 102/00

(52) U.S. Cl. CPC H10K 59/80523; H10K 59/1213; H10K 59/8792; H10K 59/38; H10K 2102/351

(57) ABSTRACT

An organic light emitting display device including: a substrate on which a plurality of pixel regions are defined; a color filter layer arranged on the substrate to correspond to each of the plurality of pixel regions and including red, green, and blue color filters; and a plurality of light emitting elements arranged on the color filter layer to correspond to the red, green, and blue color filters. Each of the plurality of light emitting elements includes an anode electrode, an organic emission layer, and a cathode electrode, and the cathode electrode includes a lower metal layer, a dielectric layer, and an upper metal layer.

### CROSS-REFERENCE TO RELATED APPLICATION

This application claims priority from and the benefit of Korean Patent Application No. 10-2025-0040275, filed on Mar. 28, 2025, which is hereby incorporated by reference for all purposes as if fully set forth herein.

### BACKGROUND

### FIELD

Embodiments of the invention relate generally to a display device, and more specifically, to an organic light emitting display device for displaying images.

### DISCUSSION OF THE BACKGROUND

As society has recently entered a full-fledged information age, interest in information displays capable of processing and presenting large volumes of data has been growing, and the demand for portable information media has been increasing. As a result, the display field has advanced rapidly, and in response, various types of lightweight and thin flat panel display devices have been developed and are receiving considerable attention.

Specific examples of such flat panel display devices include liquid crystal displays (LCDs), plasma display panels (PDPs), field emission displays (FEDs), electroluminescence displays (ELDs), and organic light emitting diode displays (OLEDs). These flat panel displays are rapidly replacing traditional cathode ray tubes (CRTs) due to their superior performance, reduced thickness, light weight, and low power consumption.

Among the flat panel displays mentioned above, the organic light emitting diode display (hereinafter referred to as OLED) is a self-emissive device and does not require a backlight as used in liquid crystal displays, so it may be made lightweight and thin.

In addition, OLEDs offer superior viewing angles and contrast ratios compared to liquid crystal displays, are advantageous in terms of power consumption, may be driven by low DC voltage, and feature fast response times. Further, since their internal components are solid-state, they are resistant to external shocks and have a wide operating temperature range.

In particular, because the manufacturing process is simple, organic light emitting displays have the advantage of significantly reducing production costs compared to existing liquid crystal displays.

Such OLEDs are being actively developed not only for use in head-mounted displays (HMDs), such as glasses-type monitor devices for virtual reality (VR) or augmented reality (AR), which are worn in the form of glasses or helmets and form a focal point at a close distance in front of the eyes, but also for a wide range of other display applications.

The above information disclosed in this Background section is only for understanding of the background of the inventive concepts, and, therefore, it may contain information that does not constitute prior art.

### SUMMARY

Organic light emitting display devices according to embodiments of the invention enable absorption of wavelengths corresponding to red, green, and blue color filter regions without a separate patterning process by applying a triple-layer cathode electrode structure, so that external light passing through the color filter is absorbed by the cathode electrode, allowing external light control without a conventional polarizing film.

Additional features of the inventive concepts will be set forth in the description which follows, and in part will be apparent from the description, or may be learned by practice of the inventive concepts.

According to one or more embodiments of the invention, an organic light emitting display device includes: a substrate on which a plurality of pixel regions are defined; a color filter layer arranged corresponding to each of the plurality of pixel regions on the substrate and including red, green, and blue color filters; and a plurality of light emitting elements arranged corresponding to the red, green, and blue color filters on the color filter layer. Each of the plurality of light emitting elements includes an anode electrode, an emission layer, and a cathode electrode, and the cathode electrode includes a lower metal layer, a dielectric layer, and an upper metal layer.

A thickness of the lower metal layer and a thickness of the upper metal layer may be different from each other.

A thickness of the lower metal layer may be less than a thickness of the upper metal layer.

A thickness of the lower metal layer may be 5 mm to 50 mm.

A thickness of the upper metal layer may be 50 mm to 200 mm.

The dielectric layer may have a thickness of 600 nm or more.

The lower metal layer and the upper metal layer may be made of a metal material including one or more of silver (Ag), aluminum (Al), gold (Au), and magnesium (Mg).

The lower metal layer and the upper metal layer may include silver (Ag).

The lower metal layer and the upper metal layer may include a silver alloy including Yb, Mg, Cu, Al, Au, or Pb.

The dielectric layer may include an oxide including SiN_{X}, SiO₂, SiON, or Al₂O₃; an organic material including a monomer, a polymer, or a polyimide (PI); a conductive material of IZO, ZnO, or ITO series; or a composite of at least two or more of these materials.

The organic light emitting display device may further include a thin film transistor disposed on the color filter layer and electrically connected to the light emitting element.

The organic light emitting display device may further include a thin film transistor disposed below the color filter layer and electrically connected to the light emitting element.

The organic light emitting display device may further include a planarization layer disposed on the substrate and covering the thin film transistor.

According to yet another embodiment of the invention, an organic light emitting display device includes: a substrate on which a plurality of pixel regions are defined; an anode layer including a plurality of anode electrode arranged on the substrate to correspond to the plurality of pixel regions; an organic emission layer disposed on the anode layer; and a cathode electrode disposed on the organic emission layer. The cathode electrode includes a lower metal layer, a dielectric layer, and an upper metal layer that are stacked in sequence.

The dielectric layer may selectively absorb light of one or more wavelength ranges according to a thickness thereof.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further

understanding of the invention and are incorporated in and constitute a part of this specification, illustrate embodiments of the invention, and together with the description serve to explain the inventive concepts.

FIG. 1 is a schematic block diagram of an organic light emitting display device according to embodiments of the invention.

FIG. 2 is a schematic circuit diagram of a sub-pixel.

FIG. 3 is a schematic diagram illustrating a planar layout of sub-pixels according to one embodiment of the invention.

FIG. 4 is a cross-sectional view of an organic light emitting display device according to one embodiment of the invention, taken along line I-I' of FIG. 3.

FIG. 5 is an enlarged cross-sectional view of section “A” of FIG. 4.

FIG. 6 is an enlarged cross-sectional view of section “B” of FIG. 4.

FIG. 7 is a cross-sectional view of an organic light emitting display device according to another embodiment of the invention.

FIG. 8 is a diagram showing the changes in absorption rate of the lower metal layer in the cathode electrode of the organic light emitting display device according to one embodiment of the invention.

FIG. 9 is a diagram illustrating the change in absorption rate depending on the thickness of the lower metal layer in the cathode electrode of the organic light emitting display device according to one embodiment of the invention.

FIG. 10 is a diagram showing the change in absorption rate according to the thickness of a dielectric layer in the cathode electrode of the organic light emitting display device according to one embodiment of the invention.

FIG. 11 is a diagram showing the changes in reflectance according to the thickness of the dielectric layer of the cathode electrode of the organic light emitting display device according to one embodiment of the invention.

FIG. 12 is a diagram showing the change in absorption rate according to the thickness of the dielectric layer of the cathode electrode of the organic light emitting display device according to one embodiment of the invention;

FIG. 13 is a diagram showing changes in absorption rate according to the thickness of the dielectric layer of a single-absorbing structure of the organic light emitting display device according to one embodiment of the invention.

FIG. 14 is a diagram showing absorption rate of harmful blue wavelengths in the dielectric layer of the cathode electrode of the organic light emitting display device according to one embodiment of the invention.

FIG. 15 is a diagram showing reflectance of harmful blue wavelengths in the dielectric layer of the cathode electrode of the organic light emitting display device according to one embodiment of the invention.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As is customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

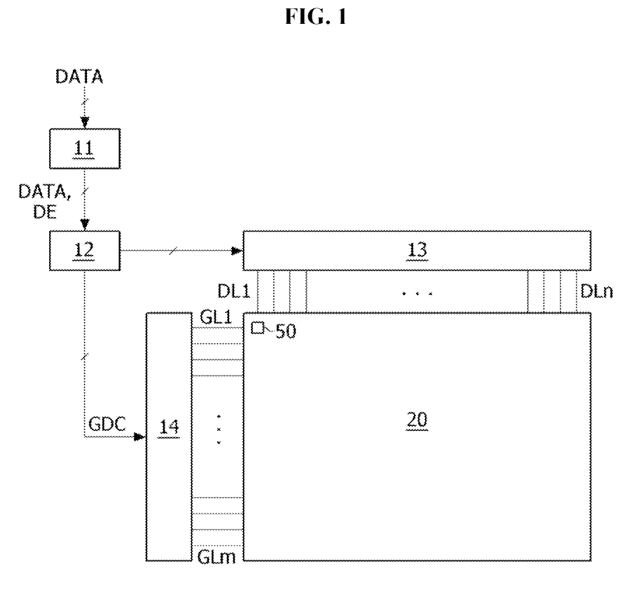

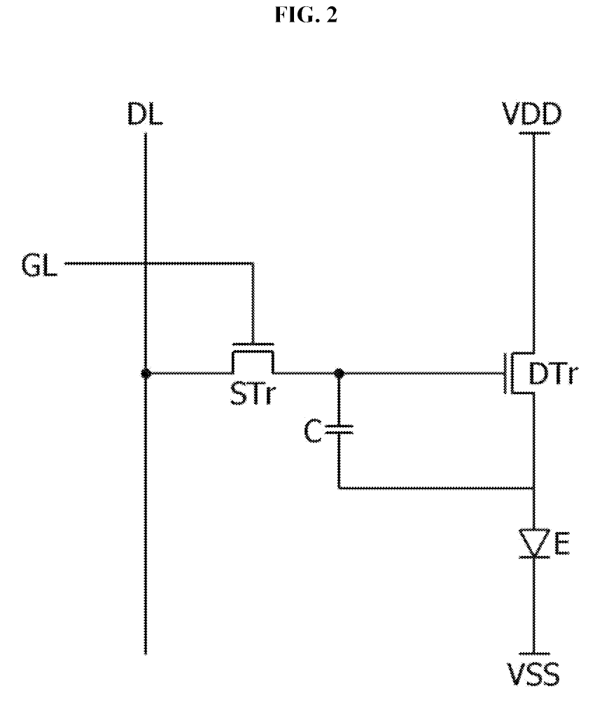

FIG. 1 is a schematic block diagram of an organic light emitting display device according to embodiments of the invention, and FIG. 2 is a schematic circuit diagram of a sub-pixel.

As shown in FIG. 1, the organic light emitting display device 100 may include an image processing unit 11, a timing controller 12, a data driver 13, a scan driver 14, and a display panel 20.

The image processing unit 11 outputs a data enable signal DEalong with a data signal DATA. In addition to the data enable signal DE, the image processing unit 11 may also output one or more of a vertical synchronization signal, a horizontal synchronization signal, and a clock signal, but these signals are omitted from the illustration for the sake of simplicity in explanation.

The timing controller 12 may receive a data signal DATA along with driving signals from the image processing unit 11, the driving signals including a data enable signal DE, or a vertical synchronization signal, a horizontal synchronization signal, and a clock signal.

The timing controller 12 may output a gate timing control signal GDC for controlling the operation timing of the scan driver 14, and a data timing control signal DDC for controlling the operation timing of the data driver 13 based on the driving signals.

In response to the data timing control signal DDC supplied from the timing controller 12, the data driver 13 may sample and latch the data signal DATA from the timing controller 12, convert it into a gamma reference voltage, and output it. The data driver 13 outputs the data signal DATA through data lines DL1 to DLn. The data driver 13 may be formed as an integrated circuit (IC).

The scan driver 14 may output a scan signal in response to the gate timing control signal GDC supplied from the timing controller 12. The scan driver 14 may output the scan signal through gate lines GL1 to GLm. The scan driver 14 may be formed in the form of an integrated circuit (IC) or may be implemented on the display panel 20 using a Gate-In-Panel (GIP) structure.

The display panel 20 may display an image in response to the data signal DATA and the scan signal supplied from the data driver 13 and the scan driver 14, respectively. The display panel 20 may include sub-pixels 50 that operate to display images.

The sub-pixels 50 include a red sub-pixel, a green sub-pixel, and a blue sub-pixel, or a white sub-pixel, a red sub-pixel, a green sub-pixel, and a blue sub-pixel. The sub-pixels 50 may have one or more different emission areas depending on their emission characteristics.

As shown in FIG. 2, a single sub-pixel may include a switching thin film transistor STr, a driving thin film transistor DTr, a capacitor C, a compensation circuit (not shown), and a light emitting element E which is an organic light emitting diode.

The switching thin film transistor STr may perform a switching operation in response to a scan signal supplied through a gate line GL so that a data signal supplied through a data line DL is stored as a data voltage in the capacitor C. The driving thin film transistor DTr may operate to allow a driving current to flow between a power supply line VDD (high potential voltage) and a cathode power line VSS (low potential voltage) according to the data voltage stored in the capacitor C. The organic light emitting element E may operate to emit light according to the driving current formed by the driving thin film transistor DTr.

The compensation circuit (not shown) is a circuit added within a sub-pixel to compensate for characteristics such as the threshold voltage of the driving thin film transistor DTr. The compensation circuit (not shown) may be composed of one or more transistors.

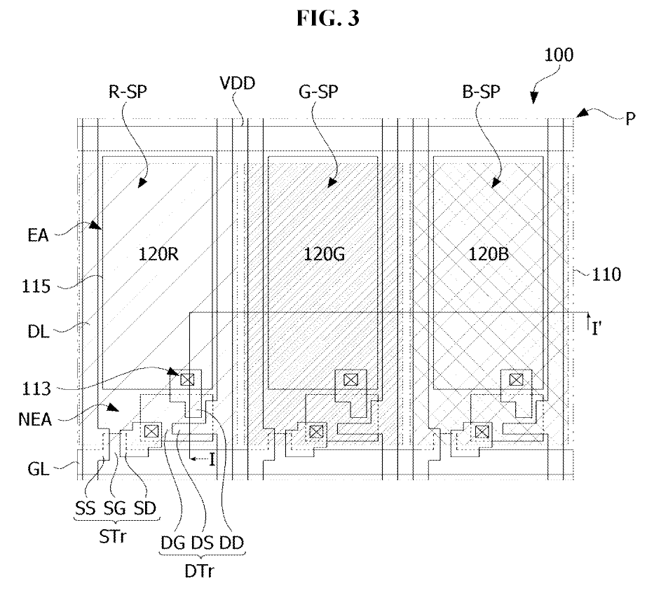

FIG. 3 is a schematic diagram illustrating a planar layout of sub-pixels according to one embodiment of the invention.

The organic light emitting display (OLED) device 100 according to one embodiment of the invention is divided into a top emission type and a bottom emission type depending on the transmission direction of the emitted light. Hereinafter, the bottom emission type will be described as an example, however, the inventive concept is not limited thereto.

Although the illustrated embodiments describe a display device with reference to a bottom-emission-type organic light emitting display device, the scope may be defined to include external light control for all types of displays to which reflective metal is applied. Furthermore, the display devices according to the inventive concept may include organic light emitting displays (OLEDs), liquid crystal displays (LCDs), micro LEDs, LEDs, e-paper displays, and the like.

Referring to FIG. 3, in the organic light emitting display (OLED) device 100 according to one embodiment of the invention, a single unit pixel P may include red, green, and blue sub-pixels R-SP, G-SP, B-SP. Each sub-pixel R-SP, G-SP, B-SP may include an emission area EA and a non-emission area NEA, and the non-emission area NEA may be arranged along the edge of the emission area EA.

Herein, for convenience of explanation, each sub-pixel R-SP, G-SP, B-SP is illustrated as being arranged side-by-side with the same width. However, the sub-pixels R-SP, G-SP, B-SP may be formed with different widths and may be configured in various structures.

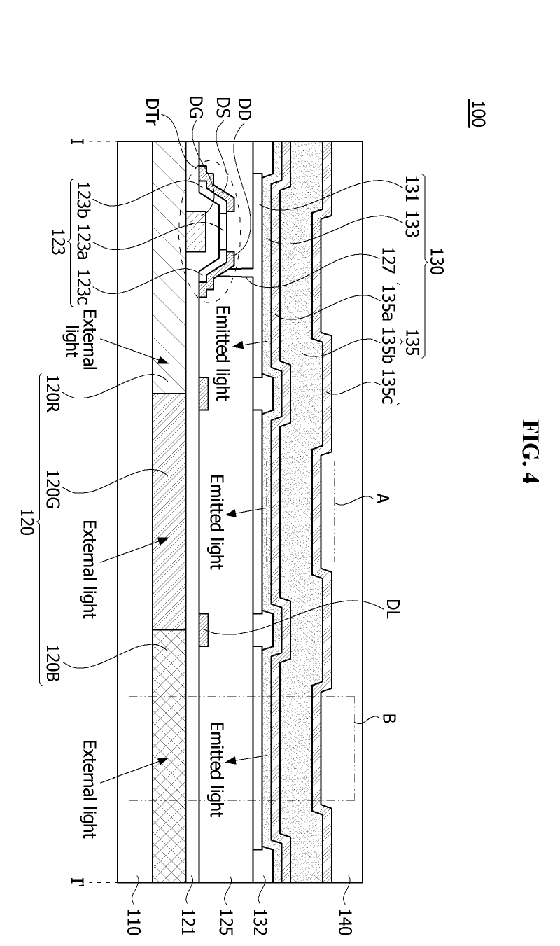

In this case, the switching thin film transistor STr and the driving thin film transistor DTr may be provided on the non-emission area NEA of each sub-pixel R-SP, G-SP, B-SP. In the emission area EA of each sub-pixel R-SP, G-SP, B-SP, a light emitting element 130 including an anode electrode 131, an organic emission layer 133, and a cathode electrode 135 (see FIG. 4) may be disposed.

The switching thin film transistor STr and the driving thin film transistor DTr may be electrically connected to each other, and the driving thin film transistor DTr may be electrically connected to the light emitting element 130.

To explain this in more detail, a gate line GL, a data line DL, and a power supply line VDD may be arranged on the substrate 110 to define each sub-pixel R-SP, G-SP, B-SP.

The switching thin film transistor STr is formed at a location where the gate line GL and the data line DL intersect, and the switching thin film transistor STr may perform the function of selecting the sub-pixels R-SP, G-SP, B-SP.

The switching thin film transistor STr may include a gate electrode SG branching from the gate line GL, a semiconductor layer 123 (see FIG. 4), a source electrode SS, and a drain electrode SD.

Further, the driving thin film transistor DTr may serve to drive the light emitting element E of the sub-pixel R-SP, G-SP, B-SP selected by the switching thin film transistor STr. The driving thin film transistor DTr may include a gate electrode DG electrically connected to the drain electrode SD of the switching thin film transistor STr, a semiconductor layer 123, a source electrode DS electrically connected to the power supply line VDD, and a drain electrode DD.

As will be described later, the drain electrode DD of the driving thin film transistor DTr may be electrically connected to the anode electrode 131 of the light emitting element E. In addition, the organic emission layer 133 may be disposed between the anode electrode 131 and the cathode electrode 135.

The organic light emitting display device 100 according to one embodiment of the invention will be described in more detail with reference to FIGS. 4 to 6.

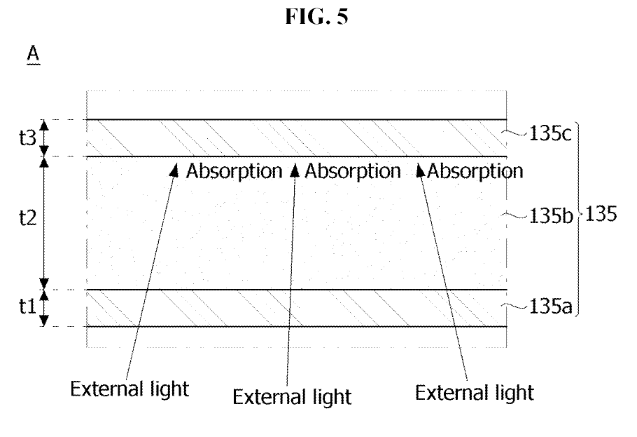

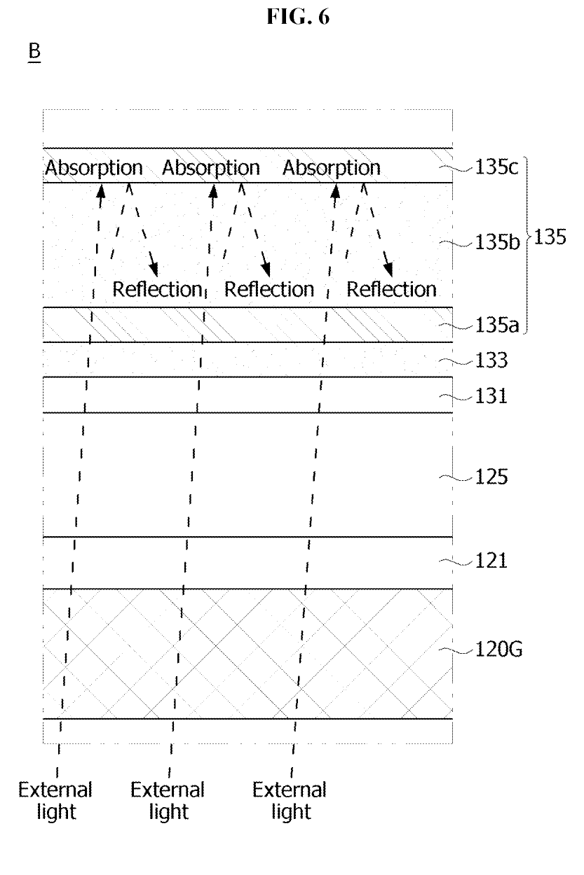

FIG. 4 is a cross-sectional view of the organic light emitting display device according to one embodiment of the invention, taken along line I-I' of FIG. 3. FIG. 5 is an enlarged cross-sectional view of section “A” of FIG. 4. FIG. 6 is an enlarged cross-sectional view of section “B” of FIG. 4.

In the present embodiment, thin film transistors having a bottom-gate structure may be provided. The bottom-gate structure may be one in which a gate electrode is first formed on a substrate, and a semiconductor layer is formed on a gate insulating film covering the gate electrode.

In another embodiment, thin film transistors having a top-gate structure may be provided. The top-gate structure refers to a structure in which the gate electrodes SG, DG are disposed on the semiconductor layer 123. That is, the top-gate structure may have a structure in which the semiconductor layer 123 is first formed on the substrate 110, and the gate electrodes SG, DG are formed on a gate insulating film 121 covering the semiconductor layer 123.

In the present embodiment, a display device having thin film transistors with the bottom-gate structure will be described.

In this case, the switching thin film transistor STr (FIG. 3) has the same structure as the driving thin film transistor DTr, and may be electrically connected to the driving thin film transistor DTr.

Furthermore, referring to FIGS. 3 and 4, the switching thin film transistor STr and the driving thin film transistor DTr may be provided as bottom gate types composed of pure and impurity-doped amorphous silicon. In another embodiment, although not shown in the drawings, the semiconductor layer 123 may be made of a polysilicon semiconductor layer or an oxide semiconductor layer, in which case the thin film transistors may be configured as top gate types.

The switching thin film transistor STr may be further formed in each sub-pixel R-SP, G-SP, B-SP on the substrate 110. In this case, the gate electrode DG of the driving thin film transistor DTr may be electrically connected to the drain electrode (not shown) of the switching thin film transistor STr, and the source electrode DS of the driving thin film transistor DTr may be electrically connected to a power supply line (not shown). In addition, the gate electrode SG (FIG. 3) and the source electrode SS (FIG. 3) of the switching thin film transistor STr may be electrically connected to the gate line and the data line, respectively, but the inventive concept is not limited thereto.

In addition, one or more sensing thin film transistors having the same structure as the driving thin film transistor DTr may be further formed in each sub-pixel R-SP, G-SP, B-SP on the substrate 110.

Referring to FIG. 4, a color filter layer 120 may be disposed on the substrate 110. The color filter layer 120 may include red, green, and blue color filters 120R, 120G, 120B corresponding to the respective sub-pixels R-SP, G-SP, B-SP. In another embodiment, as will be described later, the color filter layer 120 may be disposed between a planarization layer 125, which is positioned below the anode electrode 131 and overlaps the anode electrode 131, and an interlayer insulating film (not shown).

Further, the gate electrodes SG, DG may be arranged on the red, green, and blue color filters 120R, 120G, 120B. As another embodiment, a buffer layer (not shown) may be disposed between the gate electrodes SG, DG and the red, green, and blue color filters 120R, 120G, 120B. In this case, the buffer layer (not shown) may be formed of an inorganic insulating material such as silicon oxide (SiO_{X}) or silicon nitride (SiN_{X}), or may be formed of an organic insulating material, such as photo acryl or benzocyclobutene, for planarization of the substrate 110.

The gate electrodes SG, DG of the thin film transistors disposed in the sub-pixels R-SP, G-SP, B-SP may be arranged on the color filter layer 120.

The gate insulating film 121 covering the gate electrodes SG, DG may be disposed on the color filters 120R, 120G, 120B.

In addition, the semiconductor layer 123 may be disposed on the gate insulating film 121 covering the gate electrodes SG, DG. The semiconductor layer 123 may include an active region 123a, a source region 123b, and a drain region 123c, with the source region 123b and the drain region 123c, which are doped with high-concentration impurities, being positioned on both sides of the active region 123a.

The source electrodes SS, DS and the drain electrodes SD, DD may be disposed on the source region 123b and the drain region 123c, respectively. In this case, the source electrode SS and the drain electrode SD may constitute the switching thin film transistor STr, and the source electrode DS and the drain electrode DD may constitute the driving thin film transistor DTr.

A data line DL may be disposed on the gate insulating film 121 located in the boundary regions of the sub-pixels R-SP, G-SP, B-SP. In this case, the data line DL may be formed simultaneously with the formation of the source electrode DS and the drain electrode DD, but the inventive concept is not limited thereto.

In addition, a planarization layer 125 covering the source electrode DS, the drain electrode DD, and the data line DL may be disposed on the gate insulating film 121. In this case, as another embodiment, an interlayer insulating film (not shown) covering the source electrode DS, the drain electrode DD, and the data line DL may be disposed on the gate insulating film 121 before the formation of the planarization layer 125.

The planarization layer 125 may be formed of an inorganic insulating material such as silicon oxide (SiO_{X}) or silicon nitride (SiN_{X}), or may be formed of an organic insulating material, such as photo acryl or benzocyclobutene, for planarization of the substrate 110. However, the inventive concept is not limited thereto.

In addition, a pixel contact hole 127 may be formed in the planarization layer 125 to expose a portion of the drain electrode DD of the driving thin film transistor DTr.

The anode electrode 131 made of a conductive material may be disposed in each sub-pixel R-SP, G-SP, B-SP arranged on the above-mentioned planarization layer 125. Since the present embodiment of the invention describes the bottom emission type that emits light toward the substrate 110 side, the anode electrode 131 may be formed of a transparent conductive material.

For example, the anode electrode 131 may include at least one layered structure selected from a group of transparent conductive materials including indium-gallium-oxide (IGO), indium tin oxide (ITO), indium zinc oxide (IZO), zinc oxide (ZnO), indium oxide (In₂O₃), and aluminum zinc oxide (AZO).

In each sub-pixel R-SP, G-SP, B-SP, the anode electrode 131 may be electrically connected to the drain electrode DD of the driving thin film transistor DTr through the pixel contact hole 127. For example, the anode electrode 131 may be made of a transparent material having a relatively high work function value, and serves as the anode of the light emitting element 130.

However, the inventive concept is not limited to the above. For example, the anode electrode 131 in the present embodiment may also be applied to a case where light is emitted in an upward direction opposite to the substrate 110.

In another embodiment, in the case where light is emitted in the upward direction opposite to the substrate 110, the anode electrode 131 may be formed of a metal material with excellent light reflectivity. For example, the anode electrode 131 may be formed of any one material selected from silver (Ag), aluminum (Al), molybdenum (Mo), gold (Au), magnesium (Mg), calcium (Ca), or barium (Ba), or an alloy of two or more of these metals. Alternatively, in a top emission structure, the anode electrode 131 may have a structure in which a transparent conductive material is laminated on a metal layer with excellent light reflectivity.

In addition, a bank 132 may be disposed on the planarization layer 125 to cover the edge portion of the anode electrode 131. The bank 132 overlaps with the edge of the anode electrode 131 to cover the edge portion of the anode electrode 131, and may expose the central portion of the anode electrode 131. The bank 132 may be formed of an inorganic insulating material such as silicon oxide (SiO₂) or silicon nitride (SiN_{X}). Alternatively, the bank 132 may be formed of an organic insulating material, but the inventive concept is not limited thereto. For example, the organic insulating material may include one or more of photoresist, polyacrylate resin, epoxy resin, phenolic resin, polyamide resin, polyimide resin, unsaturated polyester resin, polyphenylene ether resin, polyphenylene sulfide resin, and benzocyclobutene.

Further, an organic emission layer 133 may be formed on the anode electrode 131 exposed through the bank 132. In this case, the organic emission layer 133 may emit white light, but the inventive concept is not necessarily limited thereto.

The organic emission layer 133 may be formed over the entire display area of the substrate 110 to cover the anode electrode 131 and the bank 132. In one example, the organic emission layer 133 may include two or more vertically stacked light emitting units to emit white light. For example, the organic emission layer 133 may include a first light emitting unit and a second light emitting unit to emit white light through the combination of first and second types of light. However, the inventive concept is not limited to the above.

As another example, the organic emission layer 133 may include any one of a blue light emitting unit, a green light emitting unit, and a red light emitting unit for emitting light corresponding to the color assigned to each pixel. In this case, the organic emission layer 133 may be formed only within the emission region defined by the bank 132. In addition, the organic light emitting element 130 may further include a functional layer for improving the emission efficiency and/or lifespan of the organic emission layer 133.

In addition, the cathode electrode 135 may be laminated on the organic emission layer 133 to form a surface contact. The cathode electrode 135 may be formed over the entire substrate 110 to be commonly electrically connected to the organic emission layer 133 formed in all pixels.

Referring to FIGS. 5 and 6, the cathode electrode 135 may have at least a triple-layer structure, and may include a lower metal layer 135a, a dielectric layer 135b, and an upper metal layer 135c. Specifically, the lower metal layer 135a may be disposed as the bottommost layer on the organic emission layer 133. In addition, the dielectric layer 135b may be disposed on the lower metal layer 135a, and the upper metal layer 135c may be disposed as the topmost layer on the dielectric layer 135b. In this case, a thickness t1 of the lower metal layer 135a may be about 5 nm to 50 nm. In addition, a thickness t3 of the upper metal layer 135c may be about 50 nm to 200 nm. However, the inventive concept is not limited to the above. Further, a thickness t2 of the dielectric layer 135b may be set to about 600 nm or more. An optimal thickness t2 of the dielectric layer 135b may be set in the range of 600 nm to 900 nm, or it may be thicker, but the inventive concept is not necessarily limited thereto. In this case, the lower metal layer 135a may be a first metal layer, and the upper metal layer 135c may be a second metal layer, but the inventive concept is not limited thereto.

In addition, the lower metal layer 135a and the upper metal layer 135c may be formed of a metal material such as silver (Ag), aluminum (Al), gold (Au), or magnesium (Mg). In the present embodiment, the lower metal layer 135a and the upper metal layer 135c may be formed of silver (Ag) as an example, but the inventive concept is not limited thereto. As another example, the lower metal layer 135a and the upper metal layer 135c may include an alloy containing silver (Ag) and other metals, such as Al. In this case, the Ag alloy material may include Yb, Mg, Cu, Al, Au, or Pb.

Further, the dielectric layer 135b may include an oxide including SiN_{X}, SiO₂, SiON, or Al₂O₃; an organic material including a monomer, a polymer, or a polyimide (PI); or a conductive material of IZO, ZnO, or ITO series, or it may include a composite of two or more of these materials.

Referring to FIGS. 5 and 6, the thickness t1 of the lower metal layer 135a and the thickness t3 of the upper metal layer 135c may be different from each other. Specifically, the thickness t1 of the lower metal layer 135a may be less than the thickness t3 of the upper metal layer 135c. The reason for this is that, when the thickness t1 of the lower metal layer 135a is less than the thickness t3 of the upper metal layer 135c, external light incident onto the rear surface of the substrate 110 of the display device 100 from the outside is first transmitted through the lower metal layer 135a, then passes through the dielectric layer 135b, and is finally completely absorbed by the upper metal layer 135c. For example, at least some or most of the external light may be absorbed through the dielectric layer 135b, and then completely absorbed in the upper metal layer 135c, but the inventive concept is not limited thereto.

Furthermore, some of the external light that is not absorbed by the upper metal layer 135c may be reflected toward the dielectric layer 135b, but this reflected light may be reabsorbed by the lower metal layer 135a.

Accordingly, external light incident onto the rear surface of the substrate 110 of the display device 100 from the outside may be completely absorbed and eliminated through the cathode electrode 135 of the triple-layer structure, so that perfect external light control may be achieved with zero or close to zero reflectance, even without the use of a conventional polarizing film.

In addition, an encapsulation layer 140 may be formed on the cathode electrode 135 with the triple-layer structure. The encapsulation layer 140 may protect the light emitting element 130 by blocking moisture or oxygen from entering from the outside. The encapsulation layer 140 may be formed of a UV-curable sealant or a frit sealant. Alternatively, the encapsulation layer 140 may have a laminated structure of an inorganic film/organic film/inorganic film. However, the inventive concept is not limited to the above.

As described above, according to the inventive concept, even if external light incident onto the rear surface of the substrate 110 of the display device 100 from the outside passes through the lower metal layer 135a and the dielectric layer 135b in the cathode electrode 135 of the organic light emitting element 130, most of the light may be absorbed by the upper metal layer 135c.

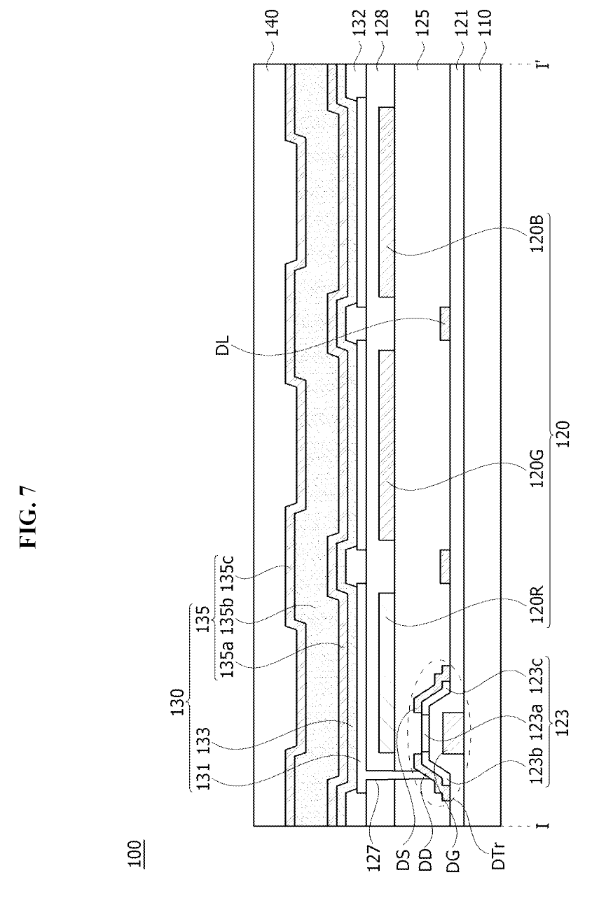

FIG. 7 is a cross-sectional view of an organic light emitting display device according to another embodiment of the invention.

Referring to FIG. 7, an organic light emitting display device 100 according to another embodiment of the invention may have the same configuration as the embodiment of the invention shown in FIG. 4, except that a color filter layer 120 including a red color filter 120R, a green color filter 120G, and a blue color filter 120B is disposed below an anode electrode 131 of a light emitting element 130.

Specifically, driving thin film transistors DTr may be arranged on a substrate 110. A planarization layer 125 may be arranged on the driving thin film transistors DTr. On the planarization layer 125, the color filter layer 120 including the red color filter 120R, the green color filter 120G, and the blue color filter 120B overlapping with the anode electrode 131 of the light emitting element 130 may be arranged.

Further, an interlayer insulating film 128 may be disposed on the planarization layer 125 to cover the red color filter 120R, the green color filter 120G, and the blue color filter 120B of the color filter layer 120.

In addition, the light emitting element 130 electrically connected to a drain electrode DD of the driving thin film transistor DTr may be disposed on the interlayer insulating film 128. In this case, the light emitting element 130 may include an anode electrode 131 electrically connected to the drain electrode DD, an organic emission layer 133, and a cathode electrode 135 having a triple-layer structure.

The configurations of the cathode electrode 135 having the triple-layer structure are the same as those described in one embodiment of the invention, so a detailed description thereof will be omitted.

As described above, according to another embodiment of the invention, external light incident onto the rear surface of the substrate 110 of the display device 100 from the outside may be completely absorbed and eliminated through the cathode electrode 135 of the triple-layer structure, so that perfect external light control may be achieved with zero or close to zero reflectance, even without the use of a conventional polarizing film.

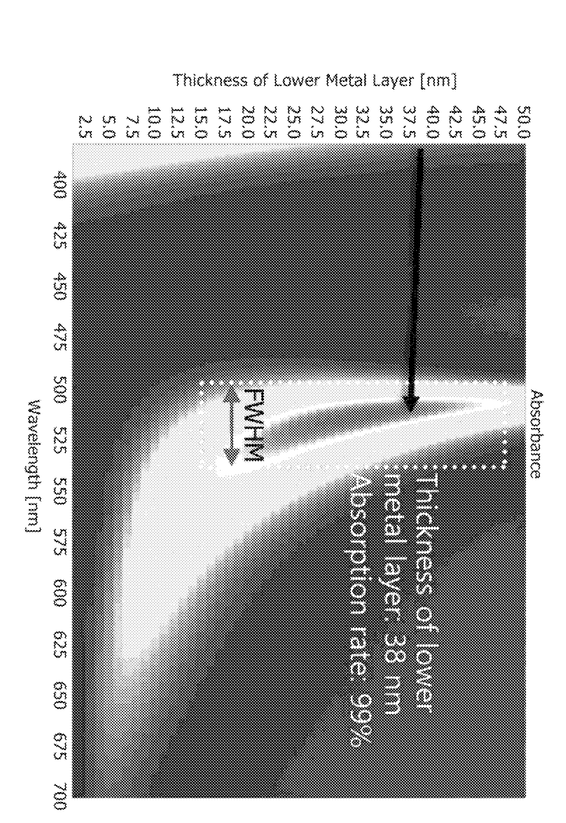

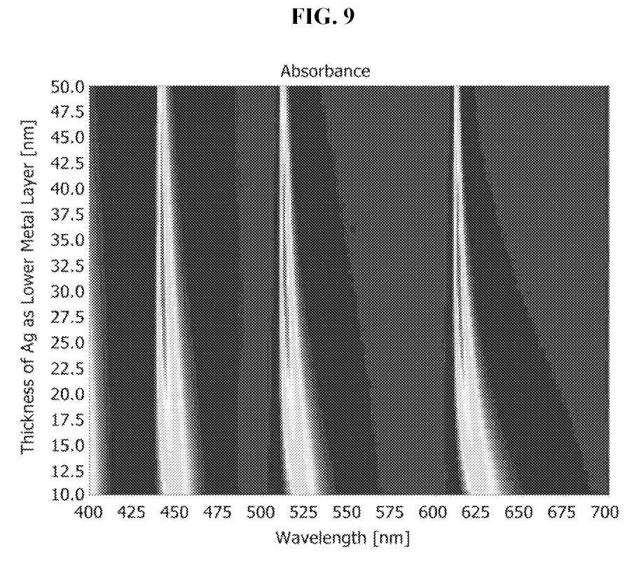

FIG. 8 is a diagram showing the changes in absorption rate of the lower metal layer in the cathode electrode of the organic light emitting display device according to one embodiment of the invention. FIG. 9 is a diagram showing the changes in absorption rate depending on the thickness of the lower metal layer in the cathode electrode of the organic light emitting display device according to one embodiment of the invention. The bidirectional arrow shown in FIG. 8 may represent a selectable range of the full width at half maximum (FWHM).

Referring to FIG. 8, this may be a case in which the thickness t1 (FIG. 5) of the lower metal layer 135a is reduced, while the thickness t3 (FIG. 5) of the upper metal layer 135c in the cathode electrode 135 is fixed at about 100 nm, which is sufficient to block light transmission, and the thickness t2 (FIG. 5) of the dielectric layer 135b is also fixed at about 100 nm.

Referring to FIG. 8, when the thickness of the lower metal layer 135a is about 0 nm, the absorption rate is about 5% or less, but as the thickness of the lower metal layer 135a increases, the absorption rate increases. For example, when the thickness t1 of the lower metal layer 135a is about 15 nm to 40 nm, the absorption rate of external light incident into the display device from the outside reaches approximately 99%.

In this case, the dielectric layer 135b functions as the layer that determines the wavelength range of light, and the upper metal layer 135c may simply serve to prevent light from being emitted upward. Therefore, based on these results, the optimal thickness t1 of the lower metal layer 135a may be fixed to about 15 nm to 40 nm, and the light absorption structure within the cathode electrode 135 may be optimized.

FIG. 9 illustrates a case where only red (R), green (G), and blue (B) wavelength bands are absorbed simultaneously without a separate patterning process. In such a case, it may be necessary to set the full width at half maximum (FWHM) of the absorption wavelength to a level similar to that of the color filter by adjusting the thickness of the lower metal layer 135a. For example, the FWHM of the absorption wavelength may need to be configured to a level similar to that of the color filter by adjusting the thickness of Ag used as the lower metal layer 135a. For instance, although the emission efficiency of the white light emitting element itself decreases by about 50% or more, considering that the light loss due to the transmittance of a conventional polarizing film is about 55.5%, this approach could be effective in terms of cost innovation.

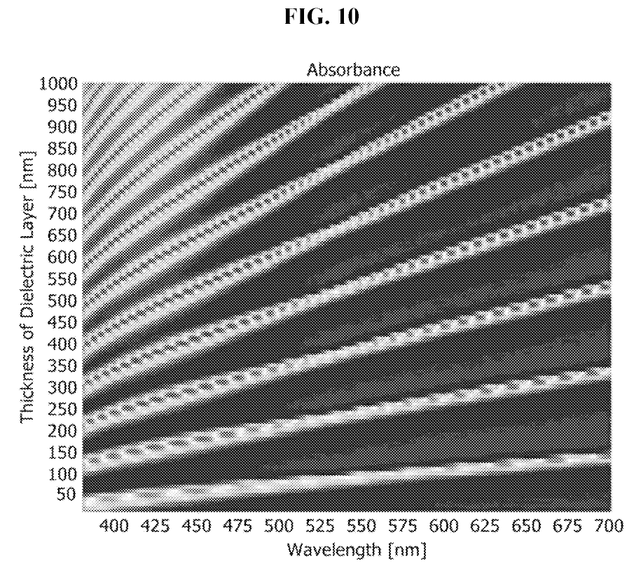

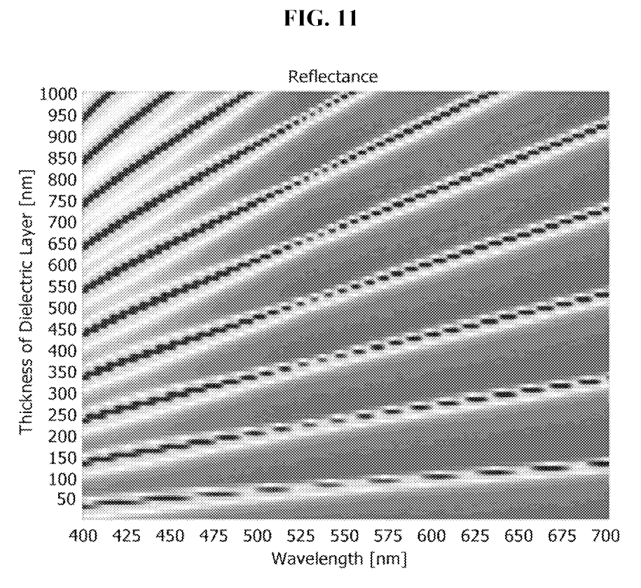

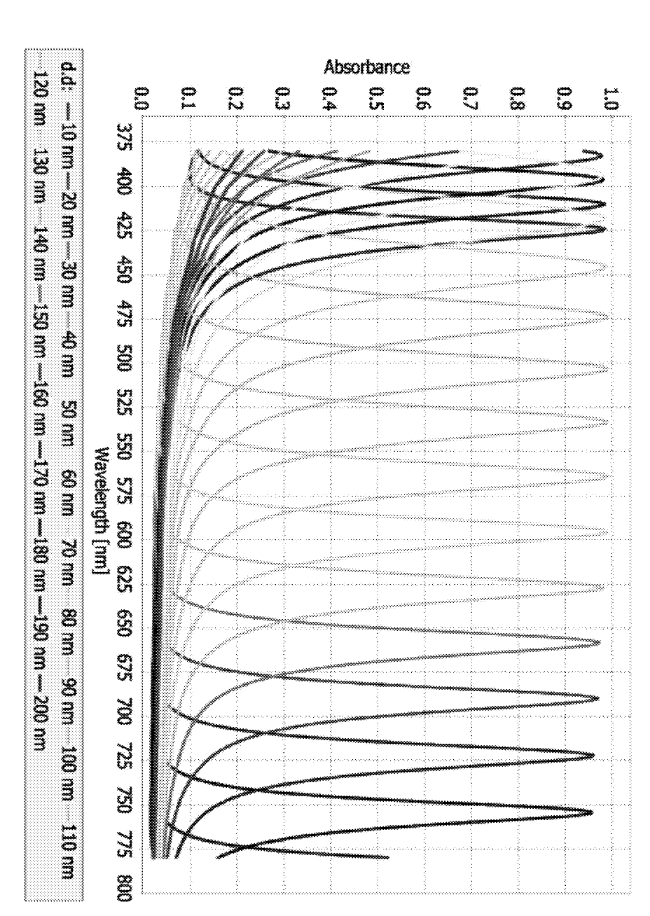

FIG. 10 is a diagram showing the change in absorption rate according to the thickness of the dielectric layer in the cathode electrode of the organic light emitting display device according to one embodiment of the invention. FIG. 11 is a diagram showing the change in reflectance according to the thickness of the dielectric layer in the cathode electrode of the organic light emitting display device according to one embodiment of the invention. FIG. 12 is a diagram showing the change in absorption rate according to the thickness of the dielectric layer in the cathode electrode of the organic light emitting display device according to one embodiment of the invention.

Referring to FIG. 10, in the absorption structure of the cathode electrode having a triple-layer structure, not only may the absorption rate of a single wavelength range be optimized depending on the thickness t2 of the dielectric layer 135b, but it is also possible to selectively absorb light of two or three wavelength ranges. In particular, by adjusting the thickness of the dielectric layer 135b, selective absorption of light in a single wavelength range or multiple wavelength ranges can be achieved. For example, when the thickness t2 of the dielectric layer 135b is set to about 750 nm, selective absorption of 90% or more may be achieved in wavelength ranges of about 450 nm, 525 nm, and 620 nm. Further, when the dielectric layer 135b is formed to have a thickness of about 400 nm, selective absorption of 90% or more may be achieved in two wavelength ranges. In addition, when the dielectric layer 135b is formed to have a thickness of about 200 nm, selective absorption of 90% or more may be achieved in one wavelength range. That is, when the thickness t2 of the dielectric layer 135b is within a range of about 600 nm to 800 nm, absorption in three wavelength bands may be achieved simultaneously. Further, when the thickness t2 of the dielectric layer 135b is within a range of about 350 nm to 600 nm, absorption in two wavelength bands may be achieved simultaneously. Further, when the thickness t2 of the dielectric layer 135b is 350 nm or less, absorption in a single wavelength band may be achieved depending on the thickness t2 of the dielectric layer 135b.

Further, referring to FIG. 11, it can be seen that, depending on the thickness of the dielectric layer, light outside the absorbed wavelength range exhibits a reflectance of 90% or more. Contrary to the description of FIG. 10, light other than the absorbed wavelength range may be reflected at 90% or more. For example, the reflectance in regions excluding the curved line shown in FIG. 11 may be 90% or more.

In addition, referring to FIG. 12, it can be confirmed that, with the thickness t1 of the lower metal layer 135a and the thickness t3 of the upper metal layer 135c optimized, the absorption rate in the wavelength range varies as the thickness t2 of the dielectric layer 135b is set from approximately 10 nm to 200 nm. As the thickness of the dielectric layer increases from about 10 nm to about 200 nm, it can be confirmed that the absorbed wavelength range shifts from a short-wavelength region to a long-wavelength region. By utilizing this characteristic, the thickness of the dielectric layer may be set so that only a desired wavelength range is selectively absorbed. For example, when the thickness of the dielectric layer is at a level of about 70nm, light in a blue wavelength range may be absorbed. Further, when the thickness of the dielectric layer is at a level of about 100nm, light in a green wavelength range may be absorbed. Further, when the thickness of the dielectric layer is at a level of about 120nm, light in a red wavelength range may be absorbed.

Consequently, it can be seen that by adjusting the thickness t2 of the dielectric layer 135b, light in a desired wavelength range may be selectively absorbed at a level of approximately 99%.

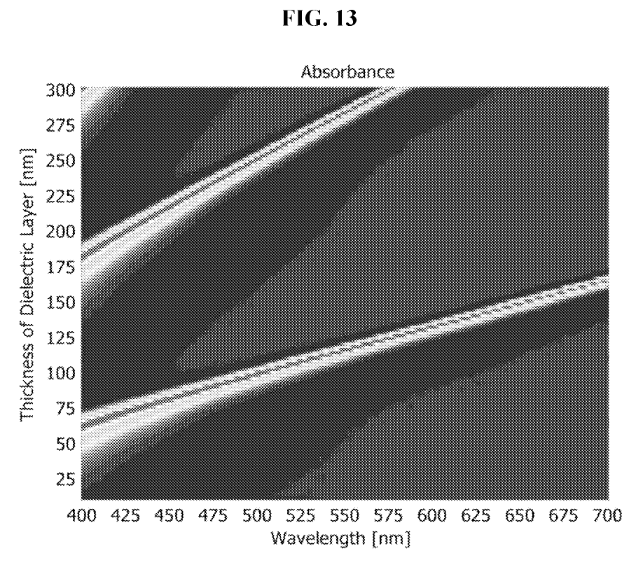

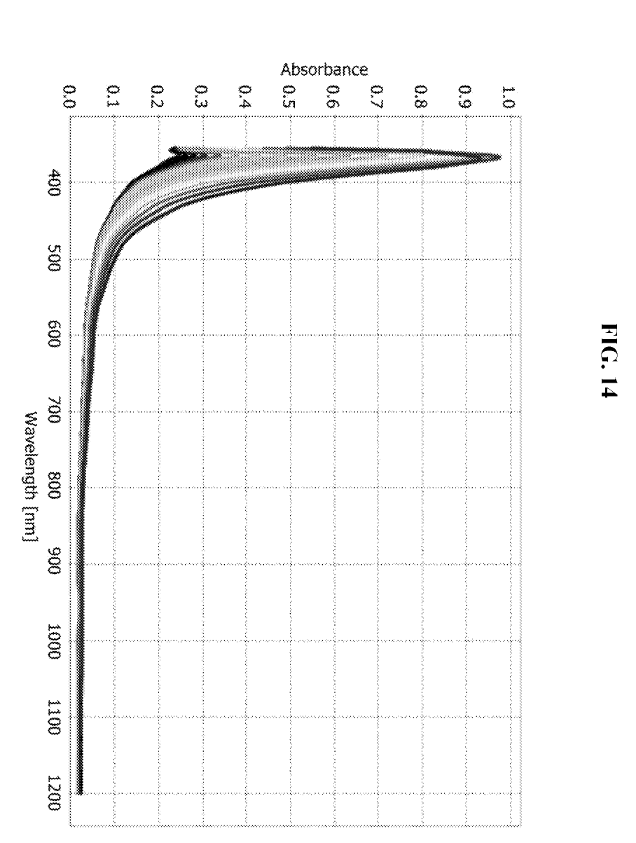

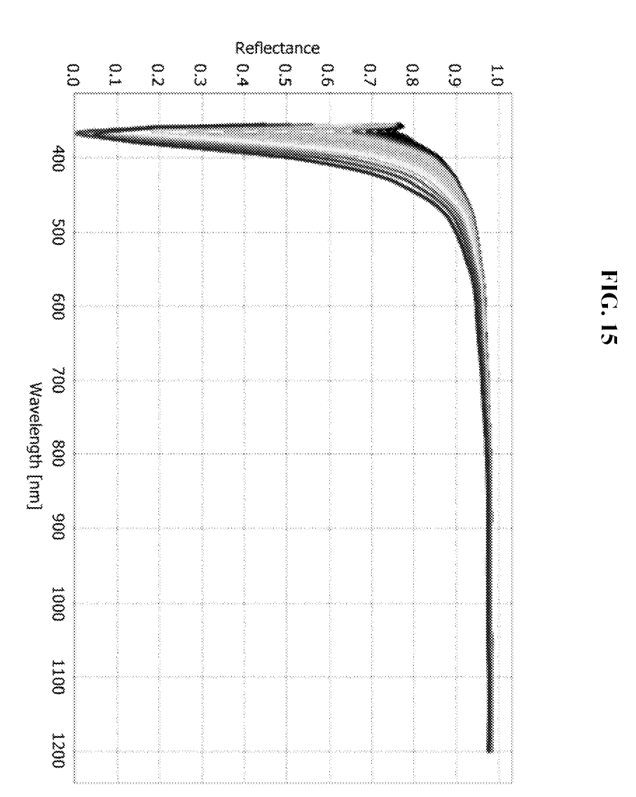

FIG. 13 is a diagram showing the change in absorption rate according to the thickness of the dielectric layer in a single absorption structure of the organic light emitting display device according to one embodiment of the invention. FIG. 14 is a diagram showing the absorption rate of harmful blue wavelengths in the dielectric layer of the cathode electrode of the organic light emitting display device according to one embodiment of the invention. FIG. 15 is a diagram showing the reflectance of harmful blue wavelengths in the dielectric layer of the cathode electrode of the organic light emitting display device according to one embodiment of the invention.

Referring to FIG. 13, this diagram shows the change in absorption rate according to the thickness of the dielectric layer 135b which allows selection of only a single absorption wavelength band, and all desired wavelength bands may be selected. For example, when the dielectric layer 135b has a thickness of about 75 nm, only light in a wavelength range of about 430 nm is absorbed, and when the dielectric layer 135b has a thickness of about 250 nm, light in a wavelength range of about 510 nm may be absorbed. For example, when the thickness of the dielectric layer 135b is within a range of about 0 nm to 300 nm, light may be selectively absorbed at a maximum level in only one wavelength range. Accordingly, in order to simultaneously select two or three or more absorption wavelength ranges, the thickness of the dielectric layer 135b may be implemented to be 300 nm or more. Further, in order to selectively absorb light of a specific single wavelength range only, the thickness of the dielectric layer 135b may be implemented to be 300 nm or less.

Further, when the harmful blue light wavelength range is selected for absorption as shown in FIG. 14, the wavelengths outside the absorption range exhibit a reflectance of approximately 95% as shown in FIG. 15.

Through this, it is possible to apply the structure to a high-grade evaluation in the TUV certification system, which classifies levels based on the percentage (%) of light in the wavelength range of about 415 nm to 455 nm within about 400 nm to 500 nm spectrum of the dielectric layer 135b.

As described above, according to embodiments of the invention, external light passing through the color filter may be absorbed through the cathode electrode with the triple-layer structure, so that perfect external light control may be achieved with zero or close to zero reflectance, even without the use of a conventional polarizing film.

According to embodiments of the invention the invention, since external light passing through the color filter may be controlled without a conventional polarizing film, the thickness of the display device may be reduced by eliminating the polarizing film, which enhances durability not only for TVs and tablets, but also for foldable displays that involve display bending.

The organic light emitting display device according to embodiments of the invention may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical device, a desktop PC, a laptop PC, a netbook computer, a workstation, a navigation system, a vehicle display device, a theater display device, a television, a wallpaper device, a signage device, a game device, a notebook, a monitor, a camera, a camcorder, and home appliances. In addition, the organic light emitting display device manufactured through a method for manufacturing the organic light emitting display device according to one or more embodiments of the invention may be applied to an organic light emitting lighting device or an inorganic light emitting lighting device.

The scope of the claims is not limited by the content of the description of the invention because the content of the invention as described in the problem to be solved, means for solving the problem, and effect described above does not specify the essential features of the claims.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. An organic light emitting display device comprising:
a substrate on which a plurality of pixel regions are defined;
a color filter layer arranged on the substrate to correspond to each of the plurality of pixel regions and including red, green, and blue color filters; and
a plurality of light emitting elements arranged on the color filter layer to correspond to the red, green, and blue color filters,
wherein:
each of the plurality of light emitting elements includes an anode electrode, an organic emission layer, and a cathode electrode; and
the cathode electrode includes a lower metal layer, a dielectric layer, and an upper metal layer.

2. The organic light emitting display device of claim 1, wherein a thickness of the lower metal layer and a thickness of the upper metal layer are different from each other.

3. The organic light emitting display device of claim 2, wherein the thickness of the lower metal layer is less than the thickness of the upper metal layer.

4. The organic light emitting display device of claim 2, wherein the thickness of the lower metal layer is in a range of 5 nm to 50 nm.

5. The organic light emitting display device of claim 2, wherein the thickness of the upper metal layer is in a range of 50 nm to 200 nm.

6. The organic light emitting display device of claim 1, wherein the dielectric layer has a thickness of 600 nm or more.

7. The organic light emitting display device of claim 1, wherein the lower metal layer and the upper metal layer include a metal material including one or more of silver (Ag), aluminum (Al), gold (Au), and magnesium (Mg).

8. The organic light emitting display device of claim 1, wherein the lower metal layer and the upper metal layer include silver (Ag).

9. The organic light emitting display device of claim 1, wherein the lower metal layer and the upper metal layer include a silver alloy material including Yb, Mg, Cu, Al, Au, or Pb.

10. The organic light emitting display device of claim 1, wherein the dielectric layer includes an oxide including SiN_{X} SiO₂ SiON, or Al₂O₃; an organic material including a monomer, a polymer, or a polyimide (PI); or a conductive material of IZO, ZnO, or ITO series, or includes a composite of at least two or more of these materials.

11. The organic light emitting display device of claim 1, further comprising a thin film transistor disposed on the color filter layer and electrically connected to the light emitting element.

12. The organic light emitting display device of claim 1, further comprising a thin film transistor disposed below the color filter layer and electrically connected to the light emitting element.

13. The organic light emitting display device of claim 11, further including a planarization layer disposed on the substrate and covering the thin film transistor.

14. An organic light emitting display device comprising:
a substrate on which a plurality of pixel regions are defined;
an anode layer including a plurality of anode electrodes disposed on the substrate to correspond to the plurality of pixel regions;
an organic emission layer disposed on the anode layer; and
a cathode electrode disposed on the organic emission layer,
wherein the cathode electrode includes a lower metal layer, a dielectric layer, and an upper metal layer that are stacked in sequence.

15. The organic light emitting display device of claim 14, wherein a thickness of the lower metal layer is in a range of 5 nm to 50 nm.

16. The organic light emitting display device of claim 14, wherein a thickness of the upper metal layer is in a range of 50 nm to 200 nm.

17. The organic light emitting display device of claim 14, wherein the dielectric layer has a thickness of 600 nm or more.

18. The organic light emitting display device of claim 17, wherein the dielectric layer includes an oxide including SiN_{X} SiO₂ SiON, or Al₂O₃; an organic material including a monomer, a polymer, or a polyimide (PI); or a conductive material of IZO, ZnO, or ITO series, or includes a composite of at least two or more of these materials.

19. The organic light emitting display device of claim 17, wherein the dielectric layer is configured to selectively absorb light of one or more wavelength ranges according to the thickness thereof.
